(19) United States
(12) Patent Application Publication
(10) Pub. No.: US 2025/0226214 A1
(43) Pub. Date: Jul. 10, 2025

(54) METHODS AND APPARATUSES FOR FILLING A GAP

(71) Applicant: ASM IP Holding B.V., Almere (NL)

(72) Inventors: Ranjit Borude, Tokyo (JP); Mikko Ruoho, Vantaa (FI); Viljami J. Pore, Helsinki (FI); Makoto Igarashi, Tokyo (JP)

(21) Appl. No.: 19/008,784

(22) Filed: Jan. 3, 2025

Related U.S. Application Data
(60) Provisional application No. 63/617,549, filed on Jan. 4, 2024.

(51) Int. Cl. H01L 21/02; C23C 16/04; C23C 16/34; C23C 16/36; C23C 16/455; C23C 16/56; H01J 37/32

(52) U.S. Cl. CPC H01L 21/02348; C23C 16/045; C23C 16/345; C23C 16/36; C23C 16/45536; C23C 16/45553; C23C 16/56; H01J 37/32357; H01J 37/32899; H01L 21/0217; H01L 21/02211

(57) ABSTRACT

The present disclosure relates to methods and systems for depositing a film comprising silicon and nitrogen. More particularly, the disclosed methods and systems perform one or more deposition cycles and a radical treatment. Optionally the methods and systems perform a thermal anneal and a vacuum ultraviolet radiation.

### CROSS-REFERENCE TO RELATED APPLICATION(S)

This application claims the benefit of U.S. Provisional Application 63/617,549 filed on Jan. 4, 2024, the entire contents of which is incorporated herein by reference.

### FIELD OF INVENTION

The present disclosure generally relates to methods and apparatuses for semiconductor manufacturing.

### BACKGROUND OF THE DISCLOSURE

The miniaturization of semiconductor devices has improved the speed and density of integrated circuits. However, owing to shrinking geometries, filling gaps in substrates for shallow trench isolation, inter-metal and passivation layers with high-quality material fully void-free has become difficult.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods that can be used to fill a gap on a substrate. While the ways in which various embodiments of the present disclosure address drawbacks of prior methods are discussed in more detail below, in general, various embodiments of the disclosure provide improved methods of fillings a gap on a substrate and improved reactor systems for filling a gap on a substrate. As explained in more detail below, use of multiple-chamber reactor systems and corresponding methods can reduce contamination associated with deposition of material, can provide deposited material with desired properties, and/or can increase throughput associated with deposition of material with desired properties and/or features.

In accordance with at least one embodiment of the disclosure, a method for filling a gap with a material comprising silicon and nitrogen is provided. The method comprises the steps of providing a substrate into a reaction chamber, wherein the substrate comprises at least one gap; depositing a material comprising silicon and nitrogen into the gap; and treating the deposited material with a radical treatment.

In some embodiments, the deposition step takes place in a deposition reaction chamber and the radical treatment step takes place in a radical treatment chamber; and the deposition reaction chamber and the radical treatment chamber are operationally coupled to allow the substrate to be transferred between them without any air break.

In some embodiments, the deposited material further comprises carbon.

In some embodiments, the deposition step comprises executing at least one deposition cycle. One deposition cycle comprises providing a silicon precursor into the reaction chamber in vapor phase; and providing a deposition plasma power to form activated species from a reactant. In some embodiments, the reactant comprises nitrogen gas. In some embodiments, the reactant comprises nitrogen gas and argon gas.

In accordance with some exemplary embodiments of the deposition step, a silicon precursor is provided into the reaction chamber to deposit a layer onto the substrate comprising at least one gap. In some embodiments, the deposited layer comprises silicon and nitrogen. Additionally, a plasma pulse is provided that comprises exposing the substrate to a plasma treatment.

In some embodiments, the silicon precursor can be any precursor comprising silicon. In some embodiments, the silicon precursor comprises aminosilane or silazane. In some embodiments, the silicon precursor is selected from group consisting of bis(diethylamino)silane, diisopropylaminosilane, N-(diethylaminosilyl)-N-ethylethanamine, N,N′-disilylsilanediamine, hexamethyldisilazane, hexamethyltrisilazane, tetramethyldivinyldisilazane, tetramethyldisilazane and tetraisocyanatosilane.

In some embodiments, the radical treatment comprises generating a remote plasma discharge; obtaining a radical flow from the remote plasma discharge; and exposing the substrate to the radical flow. In some embodiments, the remote plasma source is inductively coupled plasma. In some embodiments, the radical flow is obtained from the remote plasma discharge with an ion trap. In some embodiments, an ion trap is provided in the reaction chamber between the remote plasma discharge and the substrate. In some embodiments, the ion trap is an electrically grounded mesh plate. In some embodiments, the remote plasma discharge is produced by gas-phase ionization of a gas with a radio frequency (RF) power of 6000 W or less. In some embodiments, the remote plasma discharge is produced by gas-phase ionization of a gas with a radio frequency (RF) power of 2000 W or less. In some embodiments, the radical flow comprises hydrogen radicals. In some embodiments, the remote plasma discharge is produced by gas-phase ionization of a gas with a radio frequency (RF) power of 1000 W or less. In some embodiments, the remote plasma discharge is produced by gas-phase ionization of a gas with a radio frequency (RF) power of 600 W or less. In some embodiments, the radical flow comprises hydrogen radicals

In some embodiments, the method further comprises a thermal cure step between the deposition step and treatment step. In some embodiments, the thermal cure step takes place in a thermal cure chamber which is operationally coupled to the deposition reaction chamber and the radical treatment chamber to allow the substrate to be transferred between them without any air break.

In some embodiments, the thermal cure step comprises treating the deposited material at a temperature between 40° and 600° C.

In some embodiments, the method further comprises a step of exposing the deposited material to vacuum ultraviolet radiation.

In some embodiments, the deposited material to a vacuum ultraviolet radiation takes place in vacuum ultraviolet radiation chamber which is operationally coupled to the deposition reaction chamber the radical treatment chamber and the thermal cure chamber to allow the substrate to be transferred between them without any air break.

In some embodiments, the wavelength of the vacuum ultraviolet radiation is 100-450 nm. In some embodiments, the wavelength of the vacuum ultraviolet radiation is 172 nm.

In accordance with some embodiments of the current disclosure, a multiple-chamber reactor system is provided. The system comprises a first reaction chamber configured to deposit a material comprising silicon and nitrogen into a gap on a substrate to form a deposited material; a second reaction chamber to treat the deposited material with a radical treatment; and a controller. The controller is configured to provide the substrate comprising at least one gap into the first reaction chamber; perform a deposition cycle in the first reaction chamber; move the substrate to the second reaction chamber; and perform a radical treatment process in the second reaction chamber.

In some embodiments, the controller is configured to execute a plurality of the deposition cycles in the first reaction chamber prior to moving the substrate to the second reaction chamber.

In some embodiments, the controller is further configured to move the substrate from the second reaction chamber to the first reaction chamber.

In some embodiments, the system further comprises a third reaction chamber to thermally cure the substrate, wherein the controller is configured to move the substrate to the third reaction chamber; and perform a curing process.

In some embodiments, the system further comprises a fourth reaction chamber to expose the substrate to vacuum ultraviolet radiation, wherein the controller is configured to move the substrate to the fourth reaction chamber; and perform an exposing process.

In some embodiments, the deposition cycle comprises: pulsing a silicon precursor from a silicon precursor source to the first reaction chamber; and providing a deposition plasma power to form activated species from a reactant to deposit a material comprising silicon and nitrogen.

In some embodiments, the ultraviolet light is provided by an excimer lamp.

In some embodiments, the ultraviolet light source is a low pressure mercury lamp.

In some embodiments, the wavelength of the vacuum ultraviolet is 100-450 nm.

In some embodiments, the wavelength of the vacuum ultraviolet is 172 nm.

In some embodiments, the thermal anneal comprises heating the substrate to a temperature between 40° and 600° C.

In some embodiments, the radical treatment comprises generating a remote plasma discharge; obtaining a radical flow from the remote plasma discharge; and exposing the substrate to the radical flow.

In some embodiments, the radical flow is obtained from the remote plasma discharge with an ion trap.

In some embodiments, an ion trap is provided in the reaction chamber between the remote plasma discharge and the substrate.

In some embodiments, the ion trap is an electrically grounded mesh plate.

In some embodiments, the remote plasma discharge is produced by gas-phase ionization of a gas with a radio frequency (RF) power of 500 W or less.

In some embodiments, the remote plasma discharge is produced by gas-phase ionization of a gas with a radio frequency (RF) power of 100 W or less.

In some embodiments, the radical flow comprises hydrogen radicals.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a multiple-chamber reactor system in accordance with at least one embodiment of the disclosure.

FIG. 2 illustrates a method in accordance with at least one embodiment of the disclosure.

FIG. 3 illustrates a reaction chamber suitable for use in accordance with embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Exemplary embodiments of the disclosure provide improved systems and methods for filling a gap on a substrate. Exemplary systems and methods can be used to fill a gap with a material comprising silicon and nitrogen. Further, exemplary systems and methods can be used to deposit, treat with radicals and optionally expose to vacuum ultraviolet radiation and thermally cure materials comprising silicon and nitrogen. In some embodiments, all these steps are done in a single process module, e.g. without exposing a substrate to ambient conditions. Thus, any contamination of the surface that may otherwise result from performing the pre-deposition treatment and/or exposure to ambient conditions can be mitigated or avoided.

In this disclosure, a “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term precursor can refer to a compound that participates in the chemical reaction that produces another compound, and particularly to a compound that constitutes a film matrix or a main skeleton of a film. In some cases, the term reactant can be used interchangeably with the term precursor. The term inert gas can refer to a gas that does not take part in a chemical reaction and/or does not become a part of a film matrix to an appreciable extent. Exemplary inert gases include He, Ar, H₂, N₂ (e.g., when not activated by a plasma) and any combination thereof.

As used herein, the term “substrate” can refer to any underlying material or materials that may be used to form, or upon which, a device, a circuit, or a film may be formed. A substrate can include a bulk material, such as silicon (e.g., single-crystal silicon) and can include one or more layers overlying the bulk material. Further, the substrate can include various topologies, such as recesses, lines, and the like formed within or on at least a portion of a layer of the substrate. By way of examples, the substrate can include a surface comprising a first material and a second material, as described in more detail below.

As used herein, the term “deposited material, film and/or layer” can refer to any continuous or non-continuous structures and material, such as material deposited by the methods disclosed herein. For example, deposited material, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. Alternatively, a film or layer may consist entirely of isolated islands.

As used herein, the term “cyclical deposition” may refer to a process that includes sequential introduction of precursors and/or reactants into a reaction chamber and/or sequential plasma power pulses to deposit a layer over a substrate. Cyclical deposition processes include processing techniques, such as atomic layer deposition (ALD), cyclical chemical vapor deposition (CCVD), and plasma-enhanced ALD and CCVD.

As used herein, the term cyclical chemical vapor deposition may refer to any process wherein a substrate is sequentially exposed to two or more volatile precursors/reactants, which react and/or decompose on a substrate to produce a desired deposition.

As used herein, a “plasma” refers to an ionized gas consisting of roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, microwave plasmas, capacitively coupled plasmas (CCPs), inductively coupled plasmas (ICPs), and RF-hollow cathode (HC) plasmas, which differ in their production of excited and reactive species and, as a result, they can provide very different fluxes of the various species.

As used herein, a “direct plasma generator” may refer to an active species generator configured to form and sustain plasma within a process chamber between a perforated faceplate of a showerhead injector and a substrate support of said process chamber, whereas a “remote plasma generator” may refer to an active species generator configured to form and sustain plasma within a process chamber such that an ion trap of said process chamber is arranged between said plasma and a substrate support of said process chamber. Further, a “remote plasma generator” may refer to an active species generator configured to form and sustain plasma outside of a process chamber and to introduce active species formed in said plasma into said process chamber, for example, via an active species duct or channel.

A material comprising silicon and nitrogen can comprise, consist essentially of, or consist of silicon nitride material. Materials consisting of silicon nitride can include an acceptable amount of impurities, such as carbon, chlorine or other halogen, and/or hydrogen, which may originate from one or more precursors used to deposit the silicon nitride materials. As used herein, SiN or silicon nitride refers to a compound that includes silicon and nitrogen. SiN can be represented as SiNₓ, where x varies from, for example, about 0.5 to about 2.0, where some Si—N bonds are formed. In some cases, x may vary from about 0.9 to about 1.7, from about 1.0 to about 1.5, or from about 1.2 to about 1.4. In some embodiments, silicon nitride is formed where Si has an oxidation state of +IV and the amount of nitride in the material may vary. Silicon nitride can include silicon carbon nitride (SiCN), which includes silicon carbon and nitrogen.

In some embodiments, a material comprising silicon and nitrogen further comprises carbon. These films comprise, consists essentially of, or consist of silicon carbon nitride material. Materials consisting of silicon carbon nitride can include an acceptable amount of impurities, such as chloride or other halogen, and/or hydrogen, which may originate from one or more precursors used to deposit the silicon carbon nitride materials. As used herein, SiCN or silicon carbon nitride refers to a compound that includes silicon, carbon and nitrogen.

As used herein, a “structure” can include a substrate as described herein. Structures can include one or more layers overlying the substrate, such as one or more layers formed according to a method as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms including, constituted by and having can refer independently to typically or broadly comprising, comprising, consisting essentially of, or consisting of in some embodiments. It shall be understood that when a composition, method, device, or the like is said to comprise certain features, it means that it includes those features, and that it does not necessarily exclude the presence of other features, as long as they do not render the claim unworkable. This notwithstanding, the term comprises or includes or has includes the meaning of consists of, i.e., the case when the composition, method, device, or the like in question only includes the features, components, and/or steps that are listed, and does not contain any other features, components, steps, and the like, and includes consisting essentially of.

In this disclosure, any defined meanings do not necessarily exclude ordinary and customary meanings in some embodiments.

In accordance with at least one embodiment of the disclosure, a method for filling a gap with a material comprising silicon and nitrogen is provided. The method comprises the steps of providing a substrate into a reaction chamber, wherein the substrate comprises at least one gap; depositing a material comprising silicon and nitrogen; and treating the deposited material with a radical treatment. In some embodiments, the deposition step takes place in a deposition reaction chamber and the radical treatment step takes place in a radical treatment chamber; and the deposition reaction chamber and the radical treatment chamber are operationally coupled to allow the substrate to be transferred between them without any air break.

In some embodiments, the deposition step comprises executing at least one deposition cycle. One deposition cycle comprises providing a silicon precursor into the reaction chamber in vapor phase; and providing a deposition plasma power to form activated species from a reactant. In some embodiments, the reactant comprises nitrogen gas. In some embodiments, the reactant comprises nitrogen gas and argon gas.

In accordance with some exemplary embodiments of the deposition step, a silicon precursor is provided into the reaction chamber to deposit a layer onto the substrate comprising at least one gap. In some embodiments, the deposited layer comprises silicon and nitrogen. Additionally a plasma pulse is provided that comprises exposing the substrate to a plasma treatment. The plasma treatment allows the deposited layer to polymerize and convert into a flowable film. This flowable film will then fill the gap on the substrate without formation of any voids. The plasma treatment comprises generating a plasma using a reactant, such as a plasma gas. The plasma gas comprises at least nitrogen gas, and optionally one or more noble gas. In some embodiments, the noble gas is argon or helium.

In some embodiments, the silicon precursor can be any precursor comprising silicon. In some embodiments, the silicon precursor comprises aminosilane or silazane. In some embodiments, the silicon precursor is selected from group consisting of bis(diethylamino)silane, diisopropylaminosilane, N-(diethylaminosilyl)-N-ethylethanamine, N,N′-disilylsilanediamine, hexamethyldisilazane, hexamethyltrisilazane, tetramethyldivinyldisilazane, tetramethyldisilazane and tetraisocyanatosilane.

In some embodiments, the radical treatment comprises generating a remote plasma discharge; obtaining a radical flow from the remote plasma discharge; and exposing the substrate to the radical flow. In some embodiments, the radical flow comprises hydrogen radicals. The radical flow then reaches the surface of the substrate and reacts with the hydrogen atoms in the deposited material. As the amount of hydrogen atoms decrease in the wet etch rate ratio of the deposited material improves, in other words, the wet etch rate ratio decreases. The decrease of wet etch rate ratio is decreased by about 70% compared to a material which has not been treated with radicals. In the embodiments where the deposited material comprises carbon, the radical flow reacts with the surface of the substrate so that the amount of carbon atoms in the film is decreased. The amount of carbon atoms is decreased by at least 90% compared to a material which has not been treated with radicals.

In some embodiments, the radical flow is obtained from the remote plasma discharge with an ion trap. In some embodiments, an ion trap is provided in the reaction chamber between the remote plasma discharge and the substrate. In some embodiments, the ion trap is an electrically grounded mesh plate. In some embodiments, the remote plasma discharge is produced by gas-phase ionization of a gas with a radio frequency (RF) power of 500 W or less. In some embodiments, the remote plasma discharge is produced by gas-phase ionization of a gas with a radio frequency (RF) power of 100 W or less.

In some embodiments, the method further comprises a thermal cure step between the deposition step and treatment step. The thermal cure step improves some of the film properties of the deposited material. In some cases the thermal cure densifies the film. In some embodiments, the thermal cure step takes place in a thermal cure chamber which is operationally coupled to the deposition reaction chamber and the radical treatment chamber to allow the substrate to be transferred between them without any air break. In some embodiments, the thermal cure step comprises treating the deposited material at a temperature between 40° and 600° C.

In some embodiments, the method further comprises a step of exposing the deposited material to vacuum ultraviolet radiation. The vacuum ultraviolet radiation improves some of the film properties of the deposited material. In some cases the vacuum ultraviolet radiation promotes crosslinking of the molecules in the film. In some embodiments, the deposited material to a vacuum ultraviolet radiation takes place in vacuum ultraviolet radiation chamber which is operationally coupled to the deposition reaction chamber the radical treatment chamber and the thermal cure chamber to allow the substrate to be transferred between them without any air break.

In some embodiments, the wavelength of the vacuum ultraviolet radiation is 100-450 nm. In some embodiments, the wavelength of the vacuum ultraviolet radiation is 172 nm.

In accordance with at least some embodiments of the current disclosure, a multiple-chamber reactor system is provided. The system comprises a first reaction chamber configured to deposit a material comprising silicon and nitrogen into a gap on a substrate to form a deposited material. The system further comprises a second reaction chamber to treat the deposited material with a radical treatment and a controller. The controller is configured to provide the substrate comprising at least one gap into the first reaction chamber, perform at least one deposition cycle in the first reaction chamber, move the substrate to the second reaction chamber, and perform a radical treatment process in the second reaction chamber.

In some embodiments, the controller is configured to execute a plurality of the deposition cycles in the first reaction chamber prior to moving the substrate to the second reaction chamber. In some embodiments, the controller is further configured to move the substrate from the second reaction chamber to the first reaction chamber.

In some embodiments, the deposition cycle comprises: pulsing a silicon precursor from a silicon precursor source to the first reaction chamber; and providing a deposition plasma power to form activated species from a reactant to deposit a material comprising silicon and nitrogen.

In some embodiments, the radical treatment comprises generating a remote plasma discharge; obtaining a radical flow from the remote plasma discharge; and exposing the substrate to the radical flow. In some embodiments, the radical flow comprises hydrogen radicals.

In some embodiments, the radical flow is obtained from the remote plasma discharge with an ion trap. In some embodiments, an ion trap is provided in the reaction chamber between the remote plasma discharge and the substrate. In some embodiments, the ion trap is an electrically grounded mesh plate. In some embodiments, the remote plasma discharge is produced by gas-phase ionization of a gas with a radio frequency (RF) power of 500 W or less. In some embodiments, the remote plasma discharge is produced by gas-phase ionization of a gas with a radio frequency (RF) power of 100 W or less.

In some embodiments, the system further comprises a third reaction chamber to thermally cure the substrate, wherein the controller is configured to move the substrate to the third reaction chamber; and perform a thermal curing process. In some embodiments, the thermal curing comprises heating the substrate to a temperature between 40° and 600° C.

In some embodiments, the controller is configured to move the substrate to the first chamber to execute a plurality of deposition cycles, then move the substrate from the first chamber to the third chamber to thermally cure the substrate, then move the substrate from the third chamber to the second chamber for the radical treatment, finally the substrate can be moved back to the first chamber to start a new cycle. Plurality of these cycles can be performed in one process.

In some embodiments, the system further comprises a fourth reaction chamber to expose the substrate to vacuum ultraviolet radiation, wherein the controller is configured to move the substrate to the fourth reaction chamber; and perform an exposing process.

In some embodiments, the ultraviolet light is provided by an excimer lamp. In some embodiments, the ultraviolet light source is a low pressure mercury lamp. In some embodiments, the wavelength of the vacuum ultraviolet is 100-450 nm. In some embodiments, the wavelength of the vacuum ultraviolet is 172 nm.

In some embodiments, the controller is configured to move the substrate to the first chamber to execute a plurality of deposition cycles, then move the substrate from the first chamber to the fourth chamber to expose the substrate to vacuum ultraviolet radiation, then move the substrate from the fourth chamber to the third chamber to thermally cure the substrate, then move the substrate from the third chamber to the second chamber for the radical treatment, finally the substrate can be moved back to the first chamber to start a new cycle. Plurality of these cycles can be performed in one process.

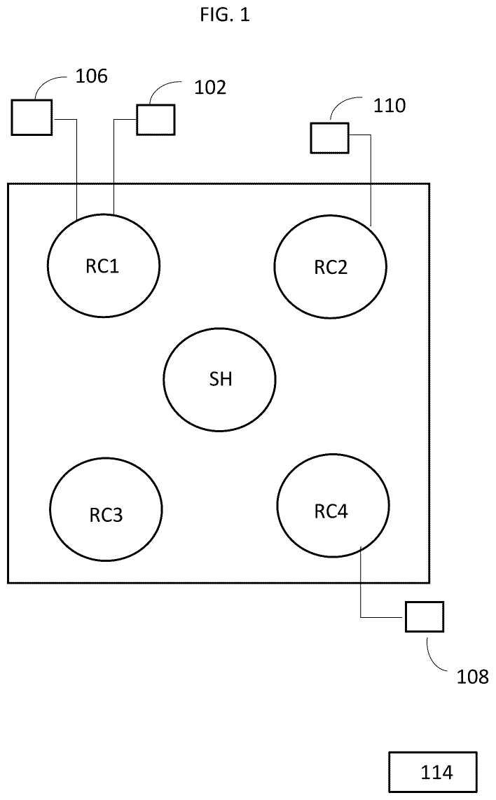

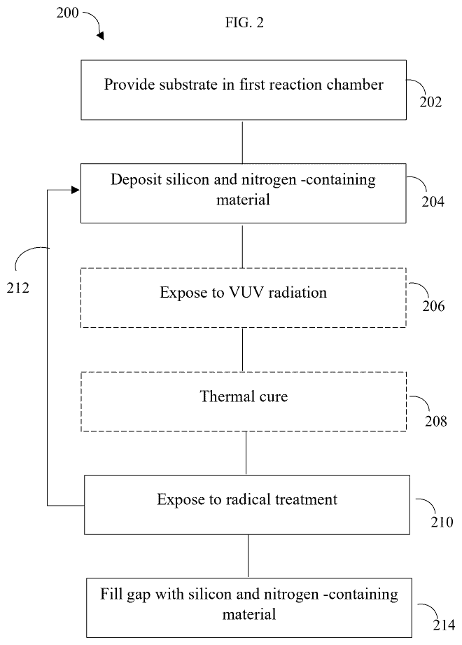

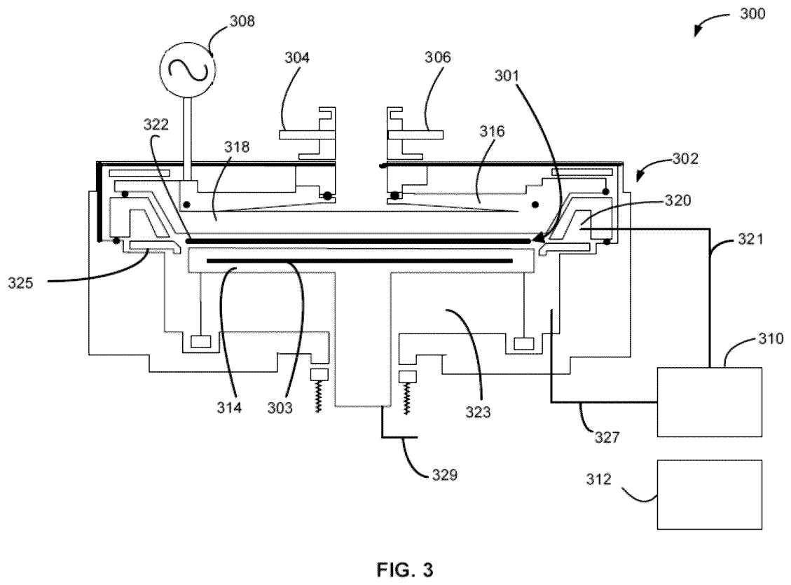

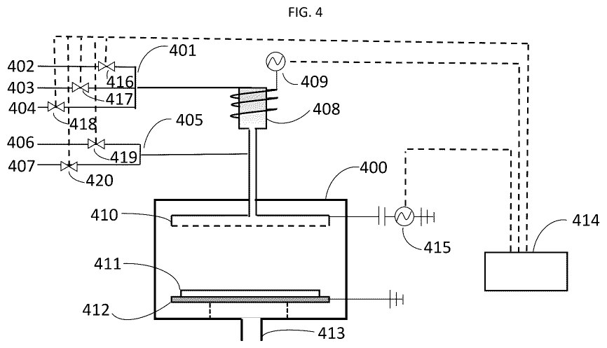

Turning now to the figures, FIG. 1 illustrates a multiple-chamber reactor system 100 in accordance with embodiments of the disclosure. In the illustrated example, multiple-chamber reactor system 100 includes a first reaction chamber RC1, a second reaction chamber RC2, a third reaction chamber RC3, and a fourth reaction chamber RC4. A configuration of RC1-RC4 can vary according to desired processes. An exemplary reaction chamber suitable for use as one or more of RC1-RC4 is described in more detail below in connection with FIG. 3.

In accordance with examples of the disclosure, at least one of RC1-RC4 is configured to deposit a material comprising silicon and nitrogen on a surface of a substrate. By way of examples, RC1 can be configured to deposit a material comprising silicon and nitrogen on a surface of the substrate.

In accordance with further examples of the disclosure, at least one of RC1-RC4 is configured to expose the deposited material to vacuum ultraviolet radiation. For example, RC2 can be configured to expose the deposited material to vacuum ultraviolet radiation.

In accordance with further examples of the disclosure, at least one of RC1-RC4 is configured to cure the deposited material with a thermal curing. For example, RC3 can be configured to cure the deposited material.

In accordance with further examples of the disclosure, at least one of RC1-RC4 is configured to treat the deposited material with a radical treatment. For example, RC4 can be configured to treat the deposited material with a radical treatment.

Multiple-chamber reactor system 100 can also include a substrate handler SH configured to move substrates between two or more reaction chambers RC1-RC4. For example, substrate handle SH (and a controller 114) can be configured to move a substrate between RC1, RC2, RC3, and RC4 and optionally repeat. Additionally or alternatively, substrate handler SH (and controller 114) can move substrates between RC1 and RC4 and repeat and/or between RC1, RC3 and RC4 and repeat.

Multiple-chamber reactor system 100 can also include a silicon precursor source 102 coupled to RC1 and/or RC3. Each silicon precursor source 102, 104 includes a vessel and a silicon precursor therein. Exemplary suitable silicon precursors are set forth above in the description. Although separately illustrated, silicon precursor source 102, 104 can be a single precursor source.

Controller 114 can be configured to move substrates within multiple-chamber reactor system 100 and to effectuate deposition and treatment processes as described herein. For example, controller 114 can be configured to provide the substrate within the first reaction chamber, perform a deposition cycle in the first reaction chamber, move the substrate to the second reaction chamber, and perform an exposure process in the second reaction chamber. By way of particular example, controller 114 can be configured to perform a deposition cycle in the first reaction chamber, wherein the deposition cycle comprises pulsing a silicon precursor from silicon precursor source 102 to first reaction chamber RC1, providing the nitrogen-containing reactant from nitrogen-containing reactant source 106 to first reaction chamber RC1, and providing a deposition plasma power to form activated species from the nitrogen-containing reactant. Additionally or alternatively, controller 114 can be configured to perform an vacuum ultraviolet radiation exposure process in second reaction chamber RC2, wherein the exposure process comprises providing vacuum ultraviolet radiation. Additionally or alternatively, controller 114 can be configured to perform thermal curing process in third reaction chamber RC3, wherein the thermal process comprises heating the reaction chamber to a temperature over 400° C. Additionally or alternatively, controller 114 can be configured to perform a radical treatment in fourth reaction chamber RC4, wherein the substrate is exposed to a radical flow. In accordance with examples of these embodiments, controller 114 is configured to execute a plurality of the deposition cycles (e.g., between about 1 and about 500 or between about 1 and 300) in first reaction chamber RC1 prior to moving the substrate to second reaction chamber RC2. In some cases, the controller is further configured to move the substrate from second reaction chamber RC2 to first reaction chamber RC1.

Turning now to the figures, FIG. 1 illustrates a multiple-chamber reactor system 100 in accordance with embodiments of the disclosure. In the illustrated example, multiple-chamber reactor system 100 includes a first reaction chamber RC1, a second reaction chamber RC2, a third reaction chamber RC3, and a fourth reaction chamber RC4. A configuration of RC1-RC4 can vary according to desired processes. An exemplary reaction chamber suitable for use as one or more of RC1-RC4 is described in more detail below in connection with FIG. 3.

In accordance with examples of the disclosure, at least one of RC1-RC4 is configured to deposit silicon-containing film on a surface of a substrate to form deposited layer comprising silicon oxide. By way of examples, RC1 and RC3 can be configured to deposit silicon-containing film on a surface of the substrate.

In accordance with further examples of the disclosure, at least one of RC1-RC4 is configured to expose the deposited layer to vacuum ultraviolet radiation. For example, RC2 and/or RC4 can be configured to treat the deposited silicon nitride.

In accordance with further examples of the disclosure, at least one of RC1-RC4 is configured to treat the exposed layer with thermal anneal. For example, RC2 and/or RC4 can be configured to treat the deposited silicon nitride.

Multiple-chamber reactor system 100 can also include a substrate handler SH configured to move substrates between two or more reaction chambers RC1-RC4. For example, substrate handle SH (and a controller 114) can be configured to move a substrate between RC1, RC2, RC3, and RC4 and optionally repeat. In these cases, third reaction chamber RC3 can be configured to deposit additional silicon-containing layer on a surface of treated and/or exposed layer and RC4 can be configured to treat the silicon-containing layer. Additionally or alternatively, substrate handler SH (and controller 114) can move substrates between RC1 and RC2 and repeat and/or between RC3 and RC4 and repeat.

Multiple-chamber reactor system 100 can also include a silicon precursor source 102 coupled to, for example, RC1. Each silicon precursor source 102 includes a vessel and a silicon precursor therein. Exemplary suitable silicon precursors are set forth below. Although separately illustrated, silicon precursor source 102 can be a single precursor source.

Multiple-chamber reactor system 100 can also include a hydrogen source 108 coupled to, for example, RC4. Each hydrogen source 108 includes a vessel and hydrogen therein.

Controller 114 can be configured to move substrates within multiple-chamber reactor system 100 and to effectuate deposition and treatment processes as described herein. For example, controller 114 can be configured to provide the substrate within the first reaction chamber, perform a deposition cycle in the first reaction chamber, move the substrate to the second reaction chamber, and perform an exposure process in the second reaction chamber.

By way of particular example, controller 114 can be configured to perform a deposition cycle in the first reaction chamber, wherein the deposition cycle comprises pulsing a silicon precursor from silicon precursor source 102 to first reaction chamber RC1, providing the nitrogen-containing reactant from nitrogen-containing reactant source 106 to first reaction chamber RC1, and providing a deposition plasma power to form activated species from the nitrogen-containing reactant. In accordance with examples of these embodiments, controller 114 is configured to execute a plurality of the deposition cycles (e.g., between about 1 and about 500 or between about 1 and 300) in first reaction chamber RC1 prior to moving the substrate to second reaction chamber RC2.

Additionally or alternatively, controller 114 can be configured to perform an exposure process in second reaction chamber RC2, wherein the exposure process comprises providing a reactant from reactant source 110 to second reaction chamber RC2 and providing vacuum ultraviolet radiation to form activated species from the reactant. In some embodiments, the reactant is selected from the list comprising ammonia, argon, nitrogen, hydrogen, oxygen and a mixture thereof.

In accordance with further examples of the disclosure, controller 114 is further configured to ramp up a flow of the reactant from reactant source 110 after the substrate is within the second reaction chamber. Controller 114 can be further configured to ramp down the flow of the reactant before the substrate is removed from the second reaction chamber. One or both of the ramp rates may be relatively constant.

Additionally or alternatively, controller 114 can be configured to perform an anneal process in third reaction chamber RC3, wherein the anneal process comprises heating the reaction chamber to a temperature over 400° C.

Additionally or alternatively, controller 114 can be configured to perform a radical treatment process in fourth reaction chamber RC4, wherein the radical process comprises exposing the substrate to a radical flow.

FIG. 2 illustrates a method 200 of filling a gap with a material comprising silicon and nitrogen in accordance with additional embodiments of the disclosure.

Method 200 includes the steps of providing a substrate within a reaction chamber (step 202), depositing a material comprising silicon and nitrogen (step 204), optionally exposing the deposited material to vacuum ultraviolet (VUV) radiation (step 206), optionally treating the exposed material with a thermal curing step (step 208), and finally exposing the material to a radical treatment to form silicon oxide-containing layer (step 210).

During step 202, a substrate is provided into a reaction chamber of a reactor. The substrate comprises at least one gap. Optionally, a reactor including the reaction chamber can be provided with a heater to activate the reactions by elevating the temperature of one or more of the substrate and/or the reactants/precursors.

During step 202, the substrate can be brought to a desired temperature and pressure for step 204. By way of examples, a temperature (e.g., of a substrate or a substrate support) within a reaction chamber can be between about 50° C. and about 200° C. or about 80° C. and about 150° C. A pressure within the reaction chamber can be about 0.5 to about 50 or about 1 to about 30 Torr.

During step 204, one or more deposition cycles are performed to deposit silicon and nitrogen-containing material on the surface of the substrate. In some cases, the deposited silicon and nitrogen-containing material is flowable. In some embodiments, the deposition the process comprises providing a silicon-containing precursor. In some embodiments, the deposition process comprises providing a silicon-containing precursor, and a plasma pulse. In some embodiments, the deposition the process comprises providing a silicon-containing precursor, providing a second precursors, and a plasma pulse. In the embodiments containing the plasma pulse, the plasma polymerizes the deposited layer to make it flowable.

In one embodiment, the deposition cycle comprises: pulsing a silicon precursor from a silicon precursor source to the first reaction chamber; and providing a deposition plasma power to form activated species from a reactant to deposit a layer comprising silicon nitride.

During step 204 a plasma power is provided for a plasma period to form activated species from the reactant gas. The deposition plasma power can have a frequency of between about 100 kHz and about 60 MHz and/or between about 12 MHz and about 14 MHz. The plasma power can have a power of between about 10 and about 2000 W or between about 100 and about 900 W or be about 30 W to about 500 W for a 300 mm diameter substrate or have similar power densities for substrates of different cross-sectional dimensions, and particularly for a CCP process. Power levels may be higher for an ICP process. A duration of step 204 can be between about 0.05 seconds and about 60 seconds or between about 0.5 seconds and about 30 seconds.

In some embodiments, a plurality of deposition cycles are performed before the substrate is moved to a second reaction chamber.

During optional step 206, the deposited layer is exposed to VUV radiation in a second reaction chamber. In some embodiments, the ultraviolet radiation is provided by an excimer lamp. In some embodiments, the ultraviolet radiation source is a low pressure mercury lamp. In some embodiments, the wavelength of the vacuum ultraviolet is 100-450 nm. In some embodiments, the wavelength of the vacuum ultraviolet is 172 nm. After the exposure step 206, the substrate is moved to the third reaction chamber for an optional anneal step 208.

During optional step 208, the exposed layer is subjected to an anneal step. In some embodiments, the anneal step comprises a thermal anneal in which the substrate is subjected to a temperature between 40° and 600° C. In some embodiments, the substrate is subjected to a temperature of about 500° C., or about 550° C. A pressure within the reaction chamber during step 208 can be between about 1 Torr and about 30 Torr or between about 2.6 Torr and about 15 Torr.

The thermal anneal densifies the formed layer as it can reduce the number of Si—H bonds in the formed layer. After the thermal anneal, the substrate can be moved to a fourth reaction chamber.

During step 210, the substrate is exposed to a radical treatment. The radical treatment is performed by exposing the substrate to a radical flow. The radical flow is obtained from a remote plasma discharge which is generated by a plasma unit. The plasma is produced by gas-phase ionization of a reactive gas using radio frequency (RF) (e.g. 13.56 MHz or 27 MHz) plasma generator. In some embodiments, the reactive gas comprises hydrogen, and optionally additionally nitrogen and/or oxygen. The plasma from the plasma unit passes through an ion trap which traps the ions from the plasma so that mainly radicals pass though as a radical flow and reach the surface of the substrate. In some embodiments the ion trap is a mesh plate. In some embodiments the radical flow comprises nitrogen radicals, hydrogen radicals, oxygen radicals or combinations thereof. Typically, the RF power for generating the plasma is maintained between 50-1000 W.

In one embodiment, the steps 204, 206, 208 and 220 can be repeated until a targeted film thickness is reached 212. The number of repeated cycles (n) is not particularly limited and may be between 1 and about 5,000. In some embodiments, the number of repeated cycles (n) is typically between 1 and about 2,000, between 1 and about 1,000, between 1 and about 500, between 1 and about 200, between 1 and about 100, or more typically between about 10 and about 1,000, more typically between about 10 and about 500, more typically between about 10 and about 200, more typically between about 10 and about 100, or even more typically between about 50 and about 1,000, even more typically between about 50 and about 500, or even more typically between about 50 and about 200. The number of repetitions of the deposition cycle (n) depends on the growth rate of the deposited material and the desired thickness of the film. In one embodiment, the substrate is exposed to a radical flow 106 after a certain number of deposition steps 104. For example, step 106 can be performed after 10 deposition cycles, or after 20 deposition cycles, or after 30 deposition cycles. The method and the individual process steps will be described in more detail below.

Finally, during step 214, the at least one gap in the substrate is filled with a material comprising silicon and nitrogen.

Turning now to FIG. 3, a reactor system 300 in accordance with exemplary embodiments of the disclosure is illustrated. Reactor system 300 can be used to perform one or more steps or substeps as described herein and/or to form one or more device structures or portions thereof as described herein.

Reactor system 300 includes a pair of electrically conductive flat-plate electrodes 314, 318 in parallel and facing each other in an interior 301 (reaction zone) of a reaction chamber 302. A plasma can be excited within reaction chamber 302 by applying, for example, plasma power from plasma power source(s) 308 to one electrode (e.g., electrode 318) and electrically grounding the other electrode (e.g., electrode 314). A temperature regulator 303 can be provided in a lower stage 314 (the lower electrode), and a temperature of a substrate 322 placed thereon can be kept at a desired temperature, such as the temperatures noted above. Electrode 318 can serve as a gas distribution device, such as a shower plate or showerhead. Precursor gases, reactant gases, and a carrier or inert gas, if any, or the like can be introduced into reaction chamber 302 using one or more gas lines (e.g., reactant gas line 304 and precursor gas line 306, respectively, coupled to a reactant source and a precursor source). For example, an inert gas and a reactant (e.g., as described above) can be introduced into reaction chamber 302 using line 304 and/or a precursor and a carrier gas (e.g., an inert gas as described above) can be introduced into the reaction chamber 302 using line 306. Although illustrated with two inlet gas lines 304, 306, reactor system 300 can include any suitable number of gas lines.

In reaction chamber 302, a circular duct 320 with an exhaust line 321 can be provided, through which gas in the interior 301 of the reaction chamber 302 can be exhausted to an exhaust source 310. Additionally, a transfer chamber 323 can be provided with a seal gas line 329 to introduce seal gas into the interior 301 of reaction chamber 302 via the interior (transfer zone) of transfer chamber 323, wherein a separation plate 325 for separating the reaction zone 301 and the transfer chamber 323 can be provided (a gate valve through which a substrate is transferred into or from transfer chamber 323 is omitted from this figure). Transfer chamber 323 can also be provided with an exhaust line 327 coupled to exhaust source 310. In some embodiments, continuous flow of a carrier gas to reaction chamber 302 can be accomplished using a flow-pass system (FPS).

Reactor system 300 can include one or more controller(s) 312 programmed or otherwise configured to cause one or more method steps as described herein to be conducted. Controller(s) 312 are coupled with the various power sources, heating systems, pumps, robotics and gas flow controllers, or valves of the reactor, as will be appreciated by the skilled artisan. By way of example, controller 312 can be configured to control gas flow of a precursor, a reactant, and an inert gas into at least one of the one or more reaction chambers to form a layer on a surface of a substrate. Controller 312 can be further configured to provide power to form a plasma—e.g., within reaction chamber 302. Controller 312 can be similarly configured to perform additional or alternative steps as described herein. By way of examples, controller 312 can be configured to perform a step of treating the deposited material, etching, and/or curing.

Controller 312 can include electronic circuitry and software to selectively operate valves, manifolds, heaters, pumps and other components included in system 300. Such circuitry and components operate to introduce precursors, reactants, and purge gases from the respective sources. Controller 312 can control timing of gas pulse sequences, temperature of the substrate and/or reaction chamber, pressure within the reaction chamber, and various other operations to provide proper operation of the system 300.

Controller 312 can include control software to electrically or pneumatically control valves to control flow of precursors, reactants, and/or purge gases into and out of the reaction chamber 302. Controller 312 can include modules, such as a software or hardware component, e.g., a FPGA or ASIC, which performs certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 300, substrates, such as semiconductor wafers, are transferred from, e.g., a substrate handling area 323 to the reaction zone 301. Once substrate(s) are transferred to reaction zone 301, one or more gases, such as precursors, reactants, carrier gases, and/or purge gases, are introduced into reaction chamber 302.

FIG. 4 shows an example of an embodiment of a radical treatment chamber where the plasma is formed using a remote plasma unit (RPU) 408 upstream of the reaction chamber 400. In some embodiments, the RPU comprises inductively coupled plasma. Optionally, a second plasma source may be provided. For example, the second plasma source 415 may be electrically connected to a showerhead 410, allowing for the showerhead to be biased relative to the susceptor 412 to form a second plasma discharge between the two. A carrier gas is supplied from a first carrier gas source 402 through a gas manifold 401 and passed through the RPU 408 into the reaction chamber 400 through the showerhead 410 that is positioned directly above a susceptor 412 on which a wafer 411 (i.e., a planar substrate) is placed. The reactive gas may be vaporized and entrained in or pulsed into the carrier gas. The apparatus is also configured to allow for the flow of other gasses from an optional third source 404 through the RPU 408.

For example, in some instances, it may be beneficial to introduce a cleaning gas (e.g., NF₃ diluted in an inert gas) periodically or even between every reaction cycle to remove any deposition from decomposed precursor chemicals in one or more of the gas lines, the gas manifold 401, RPU 408, and the showerhead 410. Additional gasses from a second source 406 (e.g., carrier, dilutant, process, feed, and/or purge gasses), may flow from a second gas manifold 405 through the showerhead 410 or from other ports (not shown) into the reaction chamber 400. Unreacted gasses and gaseous reaction by-products exit from the bottom of the reaction chamber through an exhaust line 413. The reaction chamber may optionally be equipped with a purge line and/or a pump line coupled to a vacuum pump so that the chamber may be purged between the various reaction cycles (not shown). The apparatus also comprises a controller 414 operably connected to the first, second, and third gas valves 416-418 on the first gas manifold 401, the first and second gas valves 419 and 420 on the second gas manifold 405, the RF power source for the RPU 409, the second optional RF power source 415, and other components (not shown). Optionally, the apparatus further comprises an ion trap 421 may be positioned between the showerhead 410 and the wafer 411 to restrict the plasma zone to upper portion of the chamber, above the ion trap. For example, an electrically grounded mesh plate may be used as an ion trap. In some embodiments, the mesh plate is a metal plate comprising hundreds of holes in a showerhead-like pattern that lets radical species pass through to the wafer 411 while trapping the ions. For instance, the mesh plate may comprise between about 1,000 to about 5,000 holes, each hole having a diameter between about 0.5 mm to about 2 mm. The addition of the ion trap, beneficially reduces or even eliminates interactions of electrons and ions with the wafer surface by restricting the plasma to the plasma zone in the upper portion of the reaction chamber 400.

The controller 414 is configured and programmed to independently control (e.g., turn on and off, etc.) the supply of the various gasses (e.g., carrier gas, reactive gas, and any dilutant, process, feed, and/or purging gasses etc.), the plasma source, and optionally the second plasma source, as required, to treat a film on the surface of the wafer 412 with a radical flow. For example, in some embodiments, the controller 414 opens the valve 419 to flow the reactive gas from the second source 406 into the reaction chamber 400 and turn on the RF power supply 409 in the RPU. After a set period of time, the controller 414 turns off the RF power supply 409. After a set period of time, the controller 414 closes the valve 419 to the reactive gas 406. The controller 414 is programed to repeat the various process steps to treat a film on the surface of the wafer 411 with a radical flow. The controller 414 may be programed to perform other process steps in between these various steps.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for filling a gap with a material comprising silicon and nitrogen, the method comprising the steps of:
providing a substrate into a reaction chamber, wherein the substrate comprises at least one gap;
depositing a material comprising silicon and nitrogen; and
treating the deposited material with a radical treatment.

2. The method according to claim 1, wherein the deposition step takes place in a deposition reaction chamber and the radical treatment step takes place in a radical treatment chamber; and the deposition reaction chamber and the radical treatment chamber are operationally coupled to allow the substrate to be transferred between them without any air break.

3. The method according to claim 2, wherein the method further comprises a thermal cure step between the deposition step and treatment step.

4. The method according to claim 3, wherein the thermal cure step takes place in a thermal cure chamber which is operationally coupled to the deposition reaction chamber and the radical treatment chamber to allow the substrate to be transferred between them without any air break.

5. The method according to claim 4, wherein the method further comprises a step of exposing the deposited material to vacuum ultraviolet radiation.

6. The method according to claim 5, wherein the step of exposing the deposited material to a vacuum ultraviolet radiation takes place in a vacuum ultraviolet radiation chamber which is operationally coupled to the deposition reaction chamber the radical treatment chamber and the thermal cure chamber to allow the substrate to be transferred between them without any air break.

7. The method according to claim 1, wherein the deposited material further comprises carbon.

8. The method according to claim 1, wherein the deposition step comprises executing at least one deposition cycle, one deposition cycle comprises
providing a silicon precursor into the reaction chamber in vapor phase; and
providing a deposition plasma power to form activated species from a reactant.

9. The method according to claim 8, wherein the reactant comprises nitrogen gas.

10. The method according to claim 8, wherein the reactant comprises nitrogen gas and argon gas.

11. The method according to claim 8, wherein the silicon precursor comprises aminosilane or silazane.

12. The method according to claim 8, wherein the silicon precursor is selected from group consisting of bis(diethylamino)silane, diisopropylaminosilane, N-(diethylaminosilyl)-N-ethylethanamine, N,N′-disilylsilanediamine, hexamethyldisilazane, hexamethyltrisilazane, tetramethyldivinyldisilazane, tetramethyldisilazane and tetraisocyanatosilane.

13. The method according to claim 3, wherein the thermal cure step comprises treating the deposited material at a temperature between 400° C. and 600° C.

14. The method according to claim 5, wherein the wavelength of the vacuum ultraviolet radiation is 100-450 nm.

15. The method according to claim 5, wherein the wavelength of the vacuum ultraviolet radiation is 172 nm.

16. The method according to claim 1, wherein the radical treatment comprises
generating a remote plasma discharge;
obtaining a radical flow from the remote plasma discharge; and
exposing the substrate to the radical flow.

17. The method according to claim 16, wherein the radical flow is obtained from the remote plasma discharge with an ion trap.

18. The method according to claim 17, wherein an ion trap is provided in the reaction chamber between the remote plasma discharge and the substrate.

19. The method according to claim 17, wherein the ion trap is an electrically grounded mesh plate.

20. The method according to claim 16, wherein the remote plasma discharge is produced by gas-phase ionization of a gas with a radio frequency (RF) power of 3000 W or less.

21. The method according to claim 16, wherein the remote plasma discharge is produced by gas-phase ionization of a gas with a radio frequency (RF) power of 600 W or less.

22. The method according to claim 16, wherein the radical flow comprises hydrogen radicals.
